(19) United States
(12) Patent Application Publication
(10) Pub. No.: US 2008/0153306 A1
(43) Pub. Date: Jun. 26, 2008

(54) Dry photoresist stripping process and apparatus

(75) Inventors: Seon-Mee Cho, Santa Clara, CA (US); Majeed A. Foad, Sunnyvale, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC.

(21) Appl. No.: 12/001,472

(22) Filed: Dec. 11, 2007

Related U.S. Application Data
(60) Provisional application No. 60/869,554, filed on Dec. 11, 2006.

(51) Int. Cl. H01L 21/302; C23F 1/00

(52) U.S. Cl. 438/712; 156/345.4; 257/E21.214

(57) ABSTRACT

A process for stripping photoresist from a substrate is provided. A processing system for implanting a dopant into a layer of a film stack, annealing the stripped film stack, and stripping the implanted film stack is also provided. When high dopant concentrations are implanted into a photoresist layer, a crust layer may form on the surface of the photoresist layer that may not be easily removed. The methods described herein are effective for removing a photoresist layer having such a crust on its surface.

### CROSS-REFERENCE TO RELATED APPLICATIONS

This application claims benefit of U.S. provisional patent application Ser. No. 60/869,554 (APPM/011727L), filed Dec. 11, 2006, which is herein incorporated by reference.

### BACKGROUND OF THE INVENTION

1. Field of the Invention

Embodiments of the present invention generally relate to a method for stripping photoresist from a substrate and an apparatus for its practice. Embodiments of the invention also relate to a system for implanting ions and stripping photoresist.

2. Description of the Related Art

Integrated circuits may include more than one million micro-electronic field effect transistors (e.g., complementary metal-oxide-semiconductor (CMOS) field effect transistors) that are formed on a substrate (e.g., semiconductor wafer) and cooperate to perform various functions within the circuit. During circuit fabrication, a photoresist may be deposited, exposed, and developed to create a mask utilized to etch the underlying layers.

To produce the integrated circuit, it may be necessary to implant ions into various portions of the integrated circuit. During ion implantation, wafers are bombarded by a beam of electrically charged ions, called dopants. Implantation changes the properties of the material the dopants are implanted in primarily to achieve a particular electrical performance. These dopants are accelerated to an energy that will permit them to penetrate (i.e., implant) the film to the desired depth. During implantation, ions may implant in the photoresist layer and cause a hard, crust-like layer to form on the surface of the photoresist. The crust layer is difficult to remove using conventional stripping processes. Moreover, if the crust layer or underlying photoresist is not removed, the residual resist may become a contaminant during subsequent processing steps.

Therefore, a need exists for an improved method for stripping photoresist.

### SUMMARY OF THE INVENTION

The present invention generally comprises a process for stripping photoresist from a substrate. The present invention also comprises a processing system for implanting a dopant into an integrated circuit and subsequently stripping photoresist present during the implantation step. The photoresist, and crust if present, may be effectively stripped by exposing the photoresist to water vapor and a plasma-formed from hydrogen gas and at least one of fluorine gas and oxygen gas. Annealing may then occur. By providing the implantation, stripping, and annealing within the same processing system, oxidation may be reduced and substrate throughput may be increased. The substrate throughput may be increased because a portion of the dopant may remain in the implantation chamber and be used during the implantation of the next photoresist. The portion of the dopant that remains in the implantation chamber reduces the amount of time necessary to perform the implantation for the next substrate.

In one embodiment, a photoresist stripping method comprises positioning a substrate having a photoresist layer thereon in a chamber, forming a plasma from hydrogen gas and at least one of fluorine gas and oxygen gas in a remote plasma source, introducing plasma from the remote plasma source and water vapor to the chamber, and stripping the photoresist from the substrate.

In another embodiment, a photoresist stripping method comprises disposing a substrate into processing chamber, the substrate having a photoresist layer thereover, implanting one or more ions into a layer disposed between the photoresist and the substrate, the implanting forming a crust layer out of at least a portion of the photoresist layer, igniting a plasma in a remote plasma source and exposing the crust layer to the plasma, exposing the crust layer to water vapor, and removing the crust layer and the photoresist layer.

In another embodiment, a processing system is provided for implantation, stripping, and annealing within the same processing system. One processing chamber of a processing system is configured to perform a stripping process that includes exposing the photoresist to water vapor and a plasma formed from hydrogen gas and at least one of fluorine gas and oxygen gas. Advantageously, oxidation of the substrate may be reduced and substrate throughput may be increased over conventional processes.

In another embodiment, a processing system is provided for implantation, comprising a transfer chamber, an implantation chamber coupled with the transfer chamber, a stripping chamber coupled with the transfer chamber, an annealing chamber coupled with the transfer chamber, a factory interface coupled with the transfer chamber, and one or more FOUPs coupled to the factory interface.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a sectional view of a stripping chamber according to one embodiment of the invention.

FIG. 2 is a cross-sectional view of a structure having a crusted layer formed thereon.

FIG. 3 is flow diagram of a stripping process according to one embodiment of the invention.

FIG. 4 is a schematic plan view of processing system according to the invention.

FIG. 5 is a flow diagram for different processes that may be performed in the system of FIG. 4 according to the invention.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention generally comprises a process for stripping photoresist from a film stack disposed over a substrate. The present invention also comprises a processing system for implanting a dopant into a layer of a film stack, and subsequently stripping a photoresist layer disposed on the film stack. When high dopant concentrations are implanted into the photoresist, a crust layer may form on the photoresist layer. The crust layer may form due to the photoresist losing hydrogen during the implantation. The loss of hydrogen from the surface of the photoresist layer promotes carbon bonding that creates a hard, graphite-like crust. The photoresist, including the crust, may be effectively stripped from the substrate using water vapor and a plasma of hydrogen gas and at least one of fluorine gas and oxygen gas. The stripped film stack may then be annealed. By providing the implantation, stripping, and annealing within a single processing system, oxidation of the film stack may be avoided while providing a high substrate throughput. The substrate throughput may be increased because a portion of the dopant may remain in the implantation chamber and be used during the implantation of the next photoresist. The portion of the dopant that remains in the implantation chamber reduces the amount of time necessary to perform the implantation for the next substrate.

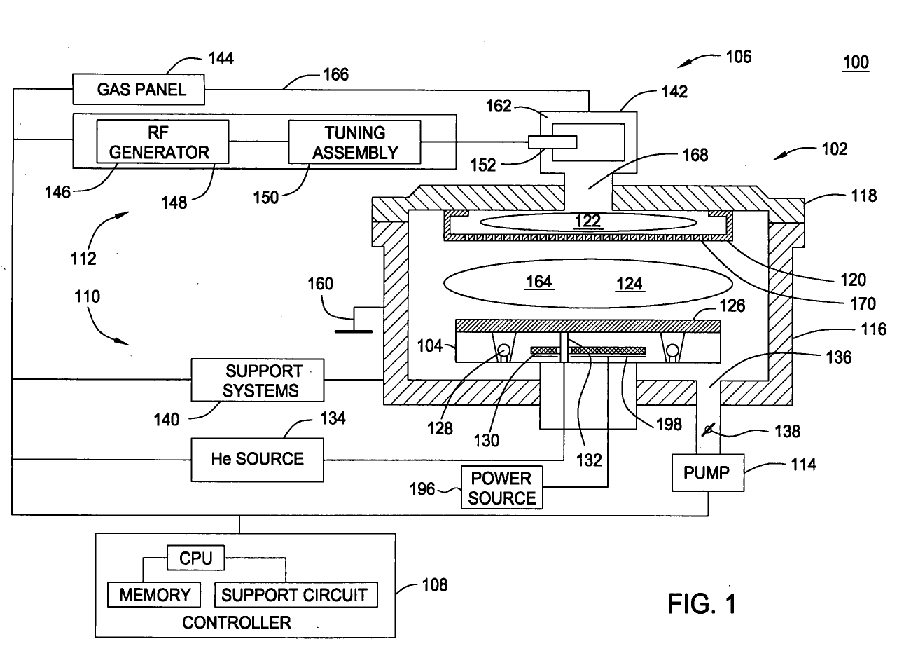

FIG. 1 is a schematic view of a stripping chamber 100 according to one embodiment of the invention. An example of a suitable stripping chamber or ashing reactor is described in detail in U.S. patent application Ser. No. 10/264,664, filed Oct. 4, 2002 and U.S. patent application Ser. No. 11/192,989, filed Jul. 29, 2005, which are herein incorporated by reference. Salient features of the reactor 100 are briefly described below.

The reactor 100 comprises a process chamber 102, a remote plasma source 106, and a controller 108. The process chamber 102 generally is a vacuum vessel, which comprises a first portion 110 and a second portion 112. In one embodiment, the first portion 110 comprises a substrate pedestal 104, a sidewall 116 and a vacuum pump 114. The second portion 112 comprises a lid 118 and a gas distribution plate (showerhead) 120, which defines a gas mixing volume 122 and a reaction volume 124. The lid 118 and sidewall 116 are generally formed from a metal (e.g., aluminum (Al), stainless steel, and the like) and electrically coupled to a ground reference 160.

The substrate pedestal 104 supports a substrate (wafer) 126 within the reaction volume 124. In one embodiment, the substrate pedestal 104 may comprise a source of radiant heat, such as gas-filled lamps 128, as well as an embedded resistive heater 130 and a conduit 132. The conduit 132 provides a gas (e.g., helium) from a source 134 to the backside of the substrate 126 through grooves (not shown) in the wafer support surface of the pedestal 104. The gas facilitates heat exchange between the support pedestal 104 and the wafer 126. The pedestal 104 may include an electrode 198 coupled to a bias power source 196 for biasing the substrate 126 during processing.

The vacuum pump 114 is coupled to an exhaust port 136 formed in the sidewall 116 of the process chamber 102. The vacuum pump 114 is used to maintain a desired gas pressure in the process chamber 102, as well as evacuate the post-processing gases and other volatile compounds from the chamber 102. In one embodiment, the vacuum pump 114 comprises a throttle valve 138 to control a gas pressure in the process chamber 102.

The process chamber 102 also comprises conventional systems for retaining and releasing the substrate 126, detecting an end of a process, internal diagnostics, and the like. Such systems are collectively depicted as support systems 140.

The remote plasma source 106 comprises a power source 146, a gas panel 144, and a remote plasma chamber 142. In one embodiment, the power source 146 comprises a radio-frequency (RF) generator 148, a tuning assembly 150, and an applicator 152. The RF generator 148 may be capable of producing about 200 W to 5000 W at a frequency of about 200 kHz to 700 kHz. The applicator 152 is inductively coupled to the remote plasma chamber 142 and energizes a process gas (or gas mixture) provided by a gas panel 144 to form a plasma 162 which is delivered to the reaction volume 124 through the showerhead 120 in the chamber. In one embodiment, the remote plasma chamber 142 has a toroidal geometry that confines the plasma and facilitates efficient generation of radical species, as well as lowers the electron temperature of the plasma. In other embodiments, the remote plasma source 106 may be a microwave plasma source. In yet other embodiments, the plasma formed in the reaction volume 124 may be formed through inductive or capacitive coupling.

The gas panel 144 uses a conduit 166 to deliver the process gas to the remote plasma chamber 142. The gas panel 144 (or conduit 166) comprises means (not shown), such as mass flow controllers and shut-off valves, to control gas pressure and flow rate for each individual gas supplied to the chamber 142. In the remote plasma chamber 142, the process gas is ionized and dissociated to form reactive species.

The reactive species are directed into the mixing volume 122 through an inlet port 168 formed in the lid 118. To minimize charge-up plasma damage to devices on the wafer 126, the ionic species of the process gas are substantially neutralized within the mixing volume 122 before the gas reaches the reaction volume 124 through a plurality of openings 170 in the showerhead 120.

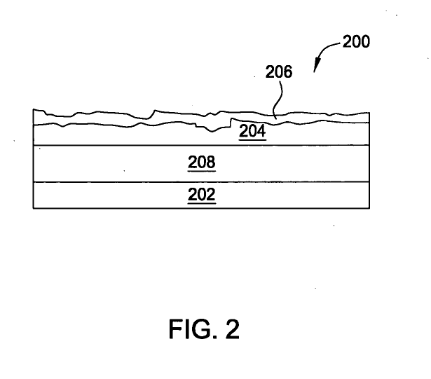

FIG. 2 is a cross-sectional view of a workpiece 200 comprising a substrate 202 having a film stack 208 and photoresist layer 204 thereon. The film stack 208, while generically shown, refers to one or more layers that may be present between the substrate 202 and the photoresist layer 204. The photoresist layer 204 may have a crusted portion 206. The crusted portion 206 may be formed on the photoresist layer 204 as a result of the photoresist layer 204 being exposed to a dopant such as phosphorus, arsenic, or boron during the implantation process.

The implantation process may cause the surface of the photoresist to lose hydrogen. Because hydrogen is lost, carbon-carbon bonds form and result in a thick carbonized crust layer. For very high doses of dopant (i.e., about 1×10¹⁵) and relatively low energy implantation, the crust. layer may contain a high concentration of dopant. In one embodiment, the dopant may comprise boron. In another embodiment, the dopant may comprise arsenic. In yet another embodiment, the dopant may comprise phosphorus. The standard photoresist representation and crust layer representation are shown below.

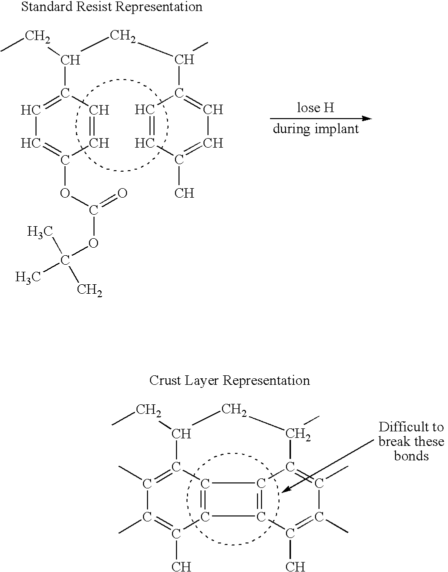

Because the crust layer comprises a dopant such as boron, phosphorus, or arsenic, removal by a conventional stripping method comprising oxygen may not be sufficient to effectively remove the crust layer 206 and the photoresist layer 204.

### Stripping Process

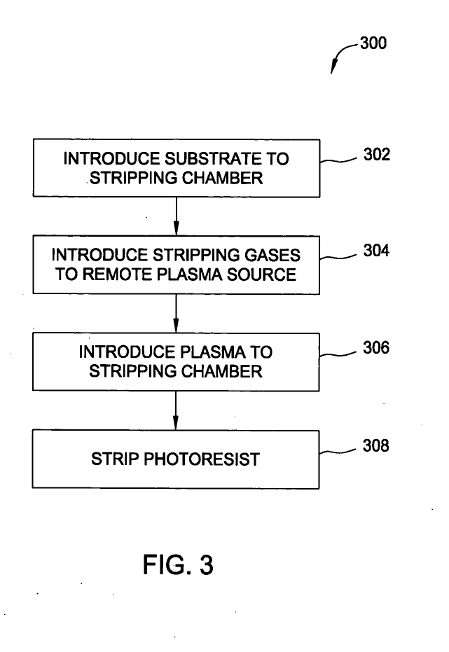

FIG. 3 is flow diagram of a stripping process 300 according to one embodiment of the invention. The process 300 begins at step 302 by introducing the workpiece 200 into the chamber 100. At step 304, a stripping gas may be introduced to the remote plasma source 142. At step 306, the plasma is introduced to the chamber 100 from the remote plasma source 142. The photoresist layer 204, including any crust layer 206 if present, is removed from the workpiece 200 by the stripping solution at step 308.

During the stripping process, the following chemical reactions occur:

—CH₂+3O₃→3O₂+CO₂+H₂O

—CH₂+2OH→CO₂+2H₂

Suitable stripping gases for the may include hydrogen, ozone, oxygen, fluorine, and water vapor. In one embodiment, hydrogen, oxygen, water vapor, and fluorine may be provided. The amount of oxygen that may be provided may be limited by safety concerns and, in one embodiment, may be eliminated by sufficient use of fluorine.

The hydrogen, fluorine, and oxygen gases are provided from the gas panel to the remote plasma source. The water vapor, on the other hand, may be produced by evaporating water remotely and then either directly provided to the processing chamber or provided by the gas panel along with the other gases. The water vapor may be kept above the boiling point of water.

In one embodiment, about 500 sccm to about 10 liters per minute of hydrogen may be provided to the chamber. In another embodiment, the amount of hydrogen provided may be about 7 liters per minute. For the water vapor, about 50 sccm to about 5 liters per minute may be provided to the chamber. In another embodiment, about 90 sccm of water vapor may be provided to the chamber. In yet another embodiment, 350 sccm of water vapor may be provided to the chamber. For fluorine, about 500 sccm may be provided to the chamber. In one embodiment, about 250 sccm of fluorine may be provided to the chamber. For oxygen, about 0 sccm to about 500 sccm may be provided to the chamber. In one embodiment, 200 sccm of oxygen may be provided to the chamber.

RF power may be provided to the remote plasma source to initiate the plasma. The RF power may be about 5 kW. The plasma may be provided to the processing chamber for stripping to occur. In one embodiment, the pressure may be up to 8 Torr. In another embodiment, the pressure may be about 2 Torr to about 5 Torr. The substrate temperature may be from about room temperature to about 350 degrees Celsius. In another embodiment, the temperature may be about 80 degrees Celsius to about 200 degrees Celsius. In yet another embodiment, the substrate temperature may be 120 degrees Celsius. In still another embodiment, the substrate temperature may be 220 degrees Celsius. If the substrate temperature is above about 350 degrees Celsius, the photoresist may begin to burn.

In one embodiment, an RF bias may be provided to the stripping chamber. The RF bias may help break up the implanted photoresist and crust layer. The RF bias may additionally provide a soft etching and help remove any residues from the substrate. The greater the magnitude of the RF bias, the more aggressive the photoresist and crust removal will be. Additionally, the greater the RF bias, the greater the likelihood of substrate damage.

The process conditions for stripping the photoresist and the crust layer from the substrate may be optimized to improve the removal rate. For example, for higher dosing rates for the implantation (i.e., greater than about 1×10¹⁶), the crust layer can be quite thick. By adjusting the amount of hydrogen, fluorine, and water vapor, the removal rate of the photoresist and the crust layer may be optimized. While discussed below in relation to boron implanted photoresist, similar results may be expected for arsenic implanted photoresist and phosphorus implanted photoresist.

### EXAMPLE 1

7 liters per minute of hydrogen was provided through a remote plasma to a processing chamber along with 90 sccm of water vapor to remove boron implanted photoresist. The boron implanted photoresist and crust layer were removed at a rate of 3000 Angstroms per minute.

### EXAMPLE 2

7 liters per minute of hydrogen was provided through a remote plasma source to a processing chamber along with 2900 sccm of water vapor to remove boron implanted photoresist. The substrate was maintained at 120 degrees Celsius, and the pressure of the chamber was maintained at 2 Torr. The boron implanted photoresist and crust layer were removed at a rate of about 300 Angstroms per minute.

### EXAMPLE 3

250 sccm of CF₄ and 5000 sccm of O₂ were provided through a remote plasma source to a processing chamber along with 350 sccm of water vapor to remove boron implanted photoresist. The substrate was maintained at a temperature of 220 degrees Celsius. The photoresist and the crusted layer were completely removed in 60 seconds.

### COMPARATIVE EXAMPLE

A conventional oxygen stripping method was used on a photoresist having a boron-containing crust layer. The process did not remove the photoresist and the crust layer as the removal rate was approximately 0 Angstroms per minute.

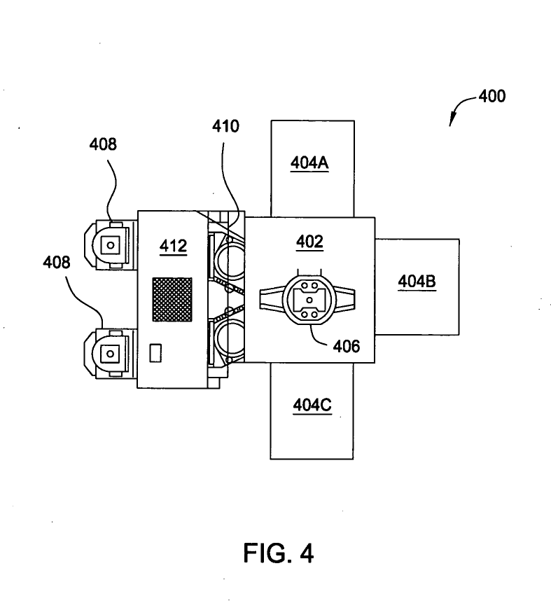

FIG. 4 is a schematic plan view of a processing system 400 according to the invention. In the embodiment shown in FIG. 4, a processing system 400 includes a central transfer chamber 402 surrounded by three processing chambers 404A-C. A factory interface 412 is coupled to the transfer chamber 402 by a load lock chamber 410. One or more FOUP's 408 are disposed in the factory interface 412 for substrate storage. A robot 406 is positioned in the central transfer chamber 402 to facilitate substrate transfer between processing chambers 404A-C and the load lock chamber 410. The substrate may be provided to the processing chambers 404A-C of the system 400 from the FOUP 408 through a load lock chamber 410 and removed from the system 400 through the load lock chamber 410 to the FOUP 408.

Each of the processing chambers 404A-B are configured to perform a different step in processing of the substrate. For example, processing chamber 404A is an implantation chamber for implanting dopants into the workpiece. An exemplary implantation chamber is a P3i® chamber, available from Applied Materials, Inc. of Santa Clara, Calif., which is discussed in U.S. patent application Ser. No. 11/608,357, filed Dec. 8, 2006, which is incorporated by reference in its entirety. It is contemplated that other suitable implantation chambers, including those produced by other manufacturers, may be utilized as well.

The chamber 404B is configured as a stripping chamber and is utilized to strip the photoresist and the crust layer from the workpiece. An exemplary stripping chamber 404B is described as the reactor 100 in FIG. 1. Suitable wet stripping chambers are also available from Applied Materials, Inc. It is contemplated that other suitable implantation chambers, including those produced by other manufacturers, may be utilized as well.

The processing chamber 404C is an annealing chamber that is utilized to anneal the workpiece after stripping. An exemplary annealing chamber that may be used is a Radiance® rapid thermal processing chamber, available from Applied Materials, Inc, which is discussed in U.S. Pat. No. 7,018,941 which is incorporated by reference in its entirety. It is contemplated that other suitable implantation chambers, including those produced by other manufacturers, may be utilized as well.

By providing the implantation, stripping, and annealing chambers on a single processing tool, substrate throughput may be increased. The substrate may be processed by first implanting the dopant into the substrate. Then, the photoresist may be stripped from the implanted substrate. Finally, the stripped substrate may be annealed.

Placing all three processing chambers 404 on the same cluster tool apparatus 400 also may increase throughput and save money. By not breaking vacuum between processing steps, the vacuum may be maintained and thus, the downtime between chamber operations may be reduced. Additionally, for the implantation chamber, about up to about 30 percent of the necessary dopant necessary for the implantation step may already be present in the implantation chamber when the next substrate arrives for processing. Unused dopant may remain in the implantation chamber and at least partially saturate the implantation chamber. By having dopant already present in the implantation chamber at the time the process begins, the photoresist may be processed faster and less dopant gas may be provided.

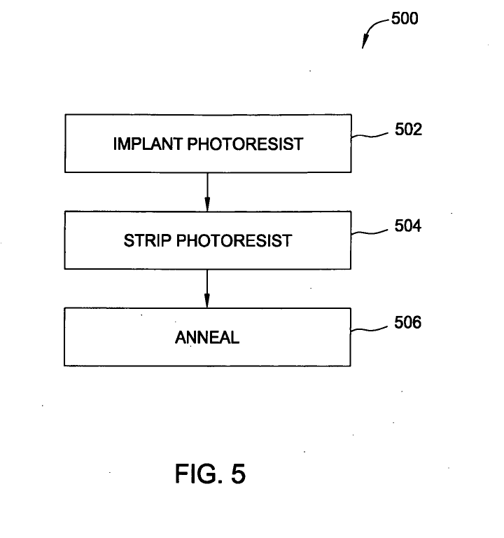

FIG. 5 is a flow diagram of a process 500 that may be performed using the processing system 400 of FIG. 4 or other suitable system. The process 500 begins at step 502 where a layer of the film stack is implanted in the chamber 404A using a method such as described in U.S. patent application Ser. No. 11/608,357, filed Dec. 8, 2006. At step 504, a photoresist layer present on the film stack during implantation is stripped in the chamber 404B using the method 300 or other suitable method. At step 506, the stripped film stack is annealed as described in U.S. Pat. No. 7,018,941.

By utilizing hydrogen, water vapor, fluorine, and oxygen, photoresist and a crust layer formed thereon may be stripped from a substrate effectively and efficiently. Integrating an implantation chamber and one or more of an annealing chamber and a stripping chamber onto a single cluster tool may increase substrate throughput and decrease costs.

While the foregoing is directed to embodiments of the present invention, other and further embodiments of the invention may be devised without departing from the basic scope thereof, and the scope thereof is determined by the claims that follow.

1. A photoresist stripping method, comprising:
positioning a substrate having a photoresist layer thereon in a stripping chamber;
forming a plasma from hydrogen gas and at least one of fluorine gas and oxygen gas in a remote plasma source;
introducing plasma from the remote plasma source and water vapor to the chamber; and
stripping the photoresist from the substrate.

2. The method of claim 1, wherein the photoresist layer is exposed to an implanting process prior to stripping.

3. The method of claim 1, further comprising:
annealing the stripped substrate.

4. The method of claim 1, further comprising:
disposing the substrate having the photoresist into an implantation chamber, implanting ions into a layer disposed between the substrate and the photoresist layer, and forming a crust layer on the photoresist;
transferring the substrate from the implantation chamber;
transferring the substrate from the stripping chamber into an annealing chamber; and
annealing the substrate.

5. The method of claim 4, wherein the ions are selected from the group consisting of boron, phosphorus, arsenic, and combinations thereof.

6. The method of claim 4, wherein the crust layer comprises two aromatic rings bonded together by two single carbon-carbon bonds.

7. The method of claim 1, wherein the stripping comprises converting the photoresist into diatomic oxygen, carbon dioxide, water, and diatomic hydrogen.

8. The method of claim 1, wherein the stripping further comprises biasing the substrate with an RF current.

9. A photoresist stripping method, comprising:
disposing a substrate into processing chamber, the substrate having a photoresist layer thereover;
implanting one or more ions into a layer disposed between the photoresist and the substrate, the implanting forming a crust layer out of at least a portion of the photoresist layer;
igniting a plasma in a remote plasma source and exposing the crust layer to the plasma;
exposing the crust layer to water vapor; and
removing the crust layer and the photoresist layer.

10. The method of claim 9, wherein the crust layer comprises two aromatic rings bonded together by two single carbon-carbon bonds.

11. The method of claim 9, wherein the implanted ions comprise boron and the plasma is ignited by flowing hydrogen gas through the remote plasma source.

12. The method of claim 11, wherein the water vapor has a flow rate of between about 80 sccm to about 100 sccm.

13. The method of claim 11, wherein the water vapor has a flow rate of between about 2800 sccm to about 3000 sccm.

14. The method of claim 9, wherein the implanted ions comprise boron and the plasma is ignited by flowing carbon tetrafluoride and oxygen through the remote. plasma source.

15. The method of claim 14, wherein the carbon tetrafluoride has a flow rate between about 225 sccm and about 275 sccm, the oxygen has a flow rate between about 4900 sccm and about 5100 sccm, and the water vapor has a flow rate between about 325 sccm and about 375 sccm.

16. The method of claim 9, wherein the ions are selected from the group consisting of boron, phosphorus, arsenic, and combinations thereof.

17. The method of claim 9, wherein the stripping comprises converting the photoresist into diatomic oxygen, carbon dioxide, water, and diatomic hydrogen.

18. The method of claim 9, further comprising annealing the substrate.

19. A processing system, comprising:
a transfer chamber;
an implantation chamber coupled with the transfer chamber;
a stripping chamber coupled with the transfer chamber;
an annealing chamber coupled with the transfer chamber;
a factory interface coupled with the transfer chamber; and
one or more FOUPs coupled to the factory interface.

20. The system of claim 19, wherein the stripping chamber comprises a remote plasma source coupled thereto.
